(19) United States
(12) Patent Application Publication
(10) Pub. No.: US 2010/0022097 A1
(43) Pub. Date: Jan. 28, 2010

(54) VAPORIZER, SEMICONDUCTOR PRODUCTION APPARATUS AND PROCESS OF SEMICONDUCTOR PRODUCTION

(75) Inventors: Hisayoshi Yamoto, Kanagawa (JP); Yuji Honda, Chiba (JP); Shinichi Koshimae, Chiba (JP)

Correspondence Address: DARBY & DARBY P.C., P.O. BOX 770, Church Street Station, New York, NY, 10008-0770, US

(73) Assignee: Youtec Co., Ltd., Chiba (JP)

(21) Appl. No.: 12/278,531

(22) PCT Filed: Feb. 27, 2006
(86) PCT No.: PCT/JP2006/303616

§ 371 Date: May 28, 2009

(51) Int. Cl. H01L 21/465

(52) U.S. Cl. 438/758; 118/726; 257/E21.485

(57) ABSTRACT

A vaporizer, a semiconductor production apparatus and process capable of improving the efficiency in the use of a raw material gas noticeably, enabling uniform deposition according to the raw material gas used, diminishing maintenance frequency to improve productivity. At the time of ALD operation, carrier gas continues to be supplied to a reaction chamber 402, while supplying a material solution of predetermined quantity according to a film thickness of one atomic or molecular layer determined by a micro-metering pump 54, intermittently to an evaporation mechanism 20. Thus, a gas shower type heat CVD apparatus 1 enables a thin film of a desired thickness made of one atomic or molecular layer to be formed on a substrate 420 one by one, while avoiding the raw material gas being thrown away by the opening or closing operation of the reaction-chamber side valve 404 and the vent side valve 407. Consequently, the efficiency in the use of the raw material gas can be improved remarkably, according to the quantity of the raw material gas that is not thrown away in the process of forming a thin film of one atomic or molecular layer one by one.

### TECHNICAL FIELD

The present invention relates to a vaporizer, a semiconductor production apparatus and a process of semiconductor production. The present invention is preferably applicable to an ALD (Atomic Layer Deposition)-type CVD (Chemical Vapor Deposition) apparatus where a material gas is intermittently supplied to a reaction chamber to grow a thin film, layer by layer with respect to an atomic or molecular layer.

### BACKGROUND ART

Semiconductor integrated circuits are manufactured by numerous repetitions of the forming and patterning of a thin film. Various kinds of CVD apparatuses are used for forming a thin film. One example of CVD apparatuses having an advantageous uniform deposition property and enabling the formation of a high quality film, is an ALD type CVD apparatus, disclosed in for example Japanese Un-examined Patent Publication No. 2006-28572, in which a raw material gas is sprayed onto a substrate intermittently, which is then heated by a heating device such as a heater to cause a chemical reaction, to thereby form a thin film on the substrate.

For example, a CVD apparatus 400 for use with ALD shown in FIG. 9 includes a CVD section 401 of a gas shower type, having a reaction chamber 402 with a gas introduction port 403 in fluid communication with a gas supply passage 405 via a valve 404 at the reaction chamber side. The gas supply passage 405 includes a branch section 406 at an upper stream side of the valve 404, and another valve 407 at a vent side is provided in this branch section 406.

An exhaust tube 408 is connected to the vent side valve 407, and thus the gas supply passage 405 is constituted so that it may be able to communicate with an exhaust vacuum pump 410 through the vent side valve 407, the exhaust tube 408, and the exhaust valve 409.

In the meantime, the reaction chamber 402 comprises a lid section 411 which has the gas introduction port 403, a reaction-chamber supporting section 412 which supports the reaction chamber 402, and a reaction-chamber body 413. The internal 415 of the reaction chamber is able to be kept at a predetermined temperature with a heater (not shown) provided in for example an outside face of the reaction chamber body 413. A shower plate 416 is provided in the internal 415 of the reaction chamber, said shower plate 416 having an interior space 417 for receiving a raw material gas from the gas introduction port 403, having two or more gas ejecting holes 418 provided in the undersurface thereof.

With the structure thus made, in the ALD-CVD apparatus 400, the valve 404 at the reaction chamber side is turned into an opened state while the vent side valve 407 into a closed state when forming a thin film, whereby a raw material gas is supplied to the reaction chamber 402, and the raw material gas is uniformly sprayed on a substrate 420 through the gas ejecting hole 418. Thus, the raw material gas is heated by the heater 422 or the like in a substrate stage 421 in the internal 415 of the reaction chamber, thus allowing a chemical reaction to occur on the substrate 420.

Thereafter, in the CVD apparatus 400 for ALD, the reaction-chamber side valve 404 is switched into a closed state at a predetermined right moment, while the vent side valve 407 into an opened state, thereby stopping the supply of a raw material gas to the internal 415 of the reaction chamber, to thereby form a thin film of one atomic layer or molecular layer of a desired deposition thickness.

Moreover, the CVD apparatus 400 for ALD is constituted such that when the forming operation of the thin film of the aforesaid one atomic layer or one molecular layer is finished, another thin film of one atomic or molecular layer of a desired film thickness is formed on the substrate 420, by performing the closing or opening operation (namely, thin-film formation operation) of the reaction chamber side valve 404 and the vent side valve 407 again after the lapse of predetermined time.

Thus, the CVD apparatuses 400 for ALD is constituted such that a raw material gas is intermittently supplied to the reaction chamber 402 to form a film of a predetermined thickness sequentially by performing the ALD operation that repeats the thin-film forming operation two or more times so that a high-density and high-quality thin film can be formed on the substrate 420.

### DISCLOSURE OF INVENTION

### Problems to be Solved by the Invention

According to such CVD apparatus 400 for ALD, however, every time a raw material gas is intermittently supplied to the reaction chamber 402, the reaction-chamber side valve 404 is switched into the closed state, while the vent side valve 407 into a closed state so that the raw material gas to be supplied to the reaction chamber 402 is supplied to the exhaust tube 408 and disposed as it is. As a result, there has been a problem that when supplying a raw material gas to the reaction chamber 402 intermittently, the efficiency in the use of a raw material gas gets worse by the disposed amount thereof.

Moreover, according to such CVD apparatus 400 for ALD, pressure and temperature in the reaction chamber interior 415 is liable to be changed easily every time the opening or closing operation of the reaction-chamber side valve 404 is repeated, so that the deposition process conditions in the internal 415 of the reaction chamber become non-uniform. As a result, there has been a problem that forming a thin film uniformly on the substrate 420 is difficult.

Furthermore, according to such CVD apparatus 400 for ALD, the opening or closing operation of the reaction-chamber side valve 404 and the vent side valve 407 is performed repeatedly, thus resulting in the increase of the opening or closing operations thereof, eventually leading to a short operating life in general. For this reason, maintenance of the reaction-chamber side valve 404 and the vent side valve 407 in a short period has been required. As a result, there has been a problem that operating ratio drops, and improvement of productivity is difficult.

The present invention has been made in view of the above problems. It is, therefore, an object of the present invention to provide a vaporizer, method and apparatus for production of a semiconductor, which enables the forming of a uniform thickness film, noticeably improving of the efficiency in the use of the raw material gas, decreasing the maintenance frequency as compared with the conventional art.

### Means for Solving the Problems

A vaporizer according to a first aspect of the invention is a vaporizer for supplying a raw material gas to a reaction chamber, said material gas being obtained by evaporating a material solution, comprising:

a carrier gas passage for allowing the carrier gas to flow from an inlet toward an outlet;

a material solution passage to which said material solution is supplied;

a connecting pipe for communicating said carrier gas passage with said material solution passage;

a material solution discharging means for determining quantity of said material solution supplied to said material passage to discharge the same to said connecting pipe;

an evaporating section provided between the outlet of said carrier gas passage and said material solution discharging means, said evaporating section evaporating a predetermined quantity of said material solution discharged from said material solution discharging means.

According to the vaporizer of a second aspect, said material solution discharging means discharges said material solution intermittently to said connecting pipe.

The vaporizer of a third aspect further comprises a solvent passage for supplying a purge solvent to said carrier gas passage.

According to the vaporizer of a fourth aspect of the invention, said carrier gas passage comprises:

a carrier gas tube to which said carrier gas is supplied;

an orifice pipe having said carrier gas supplied from said carrier gas tube, said orifice pipe turning said material solution into the form of fine particles or mists to be supplied to said evaporating section with said material solution being dispersed into the carrier gas, and

wherein said evaporating section comprises a heating means for heating and evaporating said material solution dispersed in said carrier gas.

According to the vaporizer of a fifth aspect of the invention, said material solution discharging means comprises a micro-metering pump.

According to the vaporizer of a sixth aspect of the invention, said material solution discharging means determines quantity of said material solution supplied to said material solution passage so that the determined quantity thereof corresponds to that required for a film thickness of 500 nm or less to be formed on a substrate.

According to the vaporizer of a seventh aspect of the invention, said determined quantity of the material solution corresponds to that required for forming one atomic layer or one molecular layer formed on said substrate.

According to the vaporizer of an eighth aspect of the invention, said material solution discharging means comprises a storage section for storing a specific quantity of said material solution, corresponding to that required for forming one atomic layer or one molecular layer.

According to the vaporizer of a ninth aspect of the invention, said material solution discharging means stores said specific quantity of the material solution supplied from a material solution tank in said storage section beforehand so that it may be discharged to said evaporating section at a predetermined moment.

A semiconductor production apparatus of a tenth aspect of the invention is the one including a reaction chamber for placing a substrate thereon and a vaporizer for supplying a raw material gas to the reaction chamber, said material gas being obtained by evaporating a material solution,

wherein said vaporizer comprises:

a carrier gas passage for allowing the carrier gas to flow from an inlet toward an outlet;

a material solution passage to which said material solution is supplied;

a connecting pipe for communicating said carrier gas passage with said material solution passage;

a material solution discharging means for determining quantity of said material solution supplied to said material passage to discharge the same to said connecting pipe;

an evaporating section provided between the outlet of said carrier gas passage and said material solution discharging means, said evaporating section evaporating a predetermined quantity of said material solution discharged from said material solution discharging means.

The semiconductor production apparatus of an eleventh aspect of the invention is the one wherein said material solution discharging means discharges said material solution intermittently to said connecting pipe.

The semiconductor production apparatus of a twelfth aspect of the invention further comprises a solvent passage for supplying a purge solvent to said carrier gas passage.

According to the semiconductor production apparatus of a thirteenth aspect of the invention,

said carrier gas passage comprises:

a carrier gas tube to which said carrier gas is supplied;

an orifice pipe having said carrier gas supplied from said carrier gas tube, said orifice pipe turning said material solution into the form of fine particles or mists to be supplied to said evaporating section with said material solution being dispersed into the carrier gas, and

wherein said evaporating section comprises a heating means for heating and evaporating said material solution dispersed in said carrier gas.

According to the semiconductor production apparatus of a fourteenth aspect of the invention, said material solution discharging means comprises a micro-metering pump.

According to the semiconductor production apparatus of a fifteen aspect of the invention, said material solution discharging means determines quantity of said material solution supplied to said material solution passage so that the determined quantity thereof corresponds to that required for a film thickness of 500 nm or less to be formed on a substrate.

According to the semiconductor production apparatus of a sixteenth aspect of the invention, said determined quantity of the material solution corresponds to that required for forming one atomic layer or one molecular layer formed on said substrate.

According to the semiconductor production apparatus of a seventeenth aspect of the invention, said material solution discharging means comprises a storage section for storing a specific quantity of said material solution, corresponding to that required for forming one atomic layer or one molecular layer.

According to the semiconductor production apparatus of an eighteenth aspect of the invention, said material solution discharging means stores said specific quantity of the material solution supplied from a material solution tank in said storage section beforehand so that it may be discharged to said evaporating section at a predetermined moment.

A process of producing a semiconductor of a nineteenth aspect of the invention, is the one in which a raw material gas obtained by evaporating a material solution is supplied into a reaction chamber where a substrate is surface treated, said method comprising:

a carrier gas supply step for supplying the carrier gas to said reaction chamber by allowing the carrier gas to flow from an inlet toward an outlet of a carrier gas passage;

a material-solution supply step for supplying said material solution to said material solution passage;

a quantitating step for determining quantity of said material solution supplied to said material solution passage;

a material solution discharging step for discharging a predetermined quantity of said material solution quantitated in the quantitating step to said connecting pipe communicating said carrier gas passage with said material solution passage; and

an evaporating step for evaporating said predetermined quantity of said material solution discharged in said material solution discharging step, using an evaporating section provided between the outlet of said carrier gas passage and a means for discharging said material solution.

According to the process of producing a semiconductor of a twentieth aspect of the invention, said material solution is discharged intermittently to said connecting pipe in said material solution discharging step.

The process of producing a semiconductor of a twenty-first aspect of the invention comprises a purge solvent supply step for supplying a purge solvent to said evaporating section from said carrier gas passage through said connecting pipe, instead of said material solution discharging step and said evaporating step.

According to the process of producing a semiconductor of a twenty-second aspect of the invention, said carrier gas supply step includes a sub-step for supplying said carrier gas to said orifice pipe from said carrier gas tube; and after the sub-step, said material solution is discharged to said orifice pipe in said material solution discharging step, so that said material solution turned into the form of fine particles or mists in said orifice pipe to be supplied to said evaporating section with said material solution being dispersed into the carrier gas, and then said material solution dispersed in said carrier gas through said evaporating step is heated by a heating means provided in said evaporating section.

According to the process of producing a semiconductor of a twenty-third aspect of the invention, quantity of said material solution is determined by a micro-metering pump in said quantitating step.

According to the process of producing a semiconductor of a twenty-fourth aspect of the invention, in said quantitating step, quantity of said material solution supplied to said material solution passage is determined, corresponding to that required for forming a film of 500 nm or less thickness on said substrate.

According to the process of producing a semiconductor of a twenty-fifth aspect of the invention, the quantity required for forming a film of 500 nm or less thickness corresponds to that required for forming one atomic layer or one molecular layer formed on said substrate.

According to the process of producing a semiconductor of a twenty-sixth aspect of the invention, in said quantitating step, a specific quantity of said material solution is stored in a storage section, corresponding to that required for forming one atomic layer or one molecular layer.

According to the process of producing a semiconductor of a twenty-seventh aspect of the invention, in said quantitating step, a specific quantity of the material solution supplied from a material solution tank is stored in said storage section beforehand, corresponding to that required for forming one atomic layer or one molecular layer so that it may be discharged to said evaporating section at a predetermined moment.

### EFFECTS OF THE INVENTION

According to the first, tenth and nineteenth aspects of the present invention, it possible to improve the efficiency in the use of a raw material gas noticeably, enabling uniform deposition according to the raw material gas used, diminishing maintenance frequency to improve productivity. As compared with prior art.

According to the second, eleventh and twentieth aspects of the present invention, the supply of the material solution can be repeated multiple times by the material solution discharging means, according to need.

According to the third, twelfth and twenty-first aspects of the present invention, the clogging with a solid matter can be prevented between the connecting pipes and the carrier gas passage.

According to the fourth, thirteenth and twenty-second aspects of the present invention, the material solution is turned into the form of fine particles or mists within the orifice pipe so as to be dispersed in the carrier gas in order for all the material solutions to be easily evaporated with heat, and thus all the material solution of the predetermined quantity precisely determined by the material solution discharging means can be evaporated precisely, so that a constant quantity of raw material gases can always be supplied to the reaction chamber 402 even more accurately.

According to the fifth, fourteenth and twenty-third aspects of the present invention, quantity of the material solution can be determined accurately and easily.

According to the sixth, fifteenth and twenty fourth aspects of the present invention, only the material solution corresponding to that required for forming a film of 500 nm thickness or less can be supplied to the evaporation section.

According to the seventh, sixteenth and twenty-fifth aspects of the present invention, only the material solution corresponding to that required for forming one atomic or molecular layer can be supplied to the evaporation section.

According to the eighth, seventeenth and twenty-sixth aspects of the present invention, only the material solution corresponding to that required for forming one atomic or molecular layer can be supplied to the evaporation section, by simply storing the material solution in the storage section.

According to the ninth, eighteenth and twenty-seventh aspects of the present invention, the material solution supplied from the material solution tank can be set apart by the storage section, accurate quantity of the material solution according to the film thickness of one atomic layer or one molecular layer can be discharged to the evaporation section at an optimal moment.

### BRIEF DESCRIPTION OF DRAWINGS

FIG. 1 is a schematic diagram showing an overall structure of a gas shower type heat CVD apparatus according to a first embodiment of the invention;

FIG. 2 is a schematic diagram showing a detailed structure of a vaporizer for CVD of the invention;

FIG. 3 is a schematic diagram showing an overall structure of the heat CVD apparatus according to a second embodiment of the invention;

FIG. 4 is a schematic diagram showing an overall structure of a plasma CVD apparatus according to a third embodiment of the invention;

FIG. 5 is a schematic diagram showing an overall structure of a shower type plasma CVD apparatus according to a fourth embodiment of the invention;

FIG. 6 is a schematic diagram showing an overall structure of a roller type plasma CVD apparatus according to a fifth embodiment of the invention;

FIG. 7 is a schematic diagram showing an overall structure of a roller type plasma CVD apparatus according to a sixth embodiment of the invention;

FIG. 8 is a schematic diagram showing an overall structure of a roller type heat CVD apparatus according to a seventh embodiment of the invention;

FIG. 9 is a schematic diagram showing an overall structure of a conventional ALD type CVD apparatus according to a prior art.

### BEST MODE FOR CARRYING OUT THE INVENTION

Next is description of embodiments of the present invention with reference to the attached drawings.

### (1) First Embodiment

### (1-1) Overall Structure of a Vertical Gas Shower Type Heat CVD Apparatus

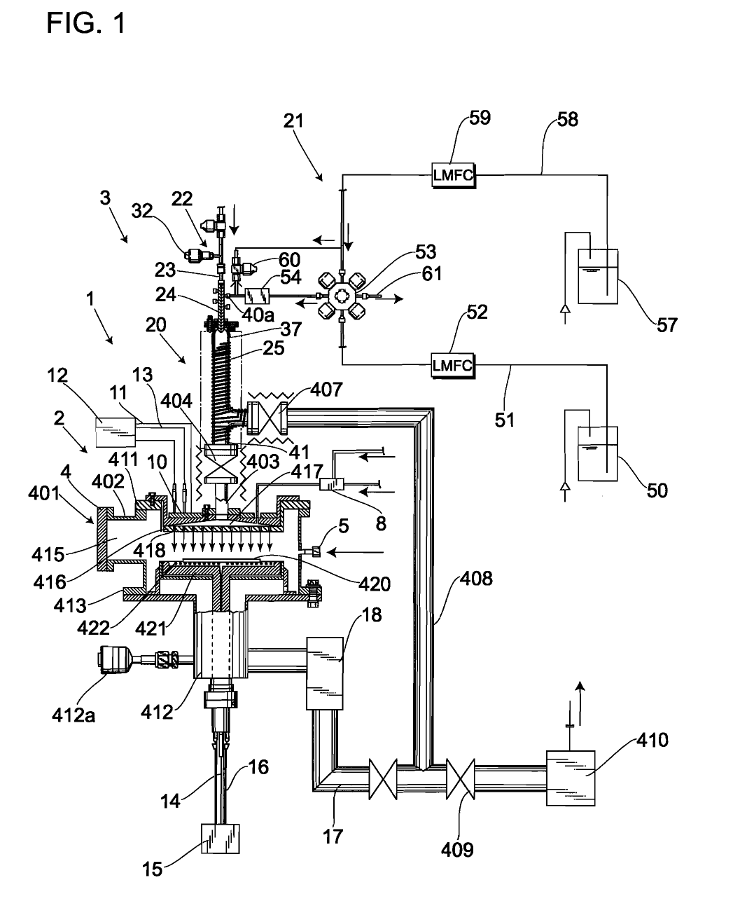

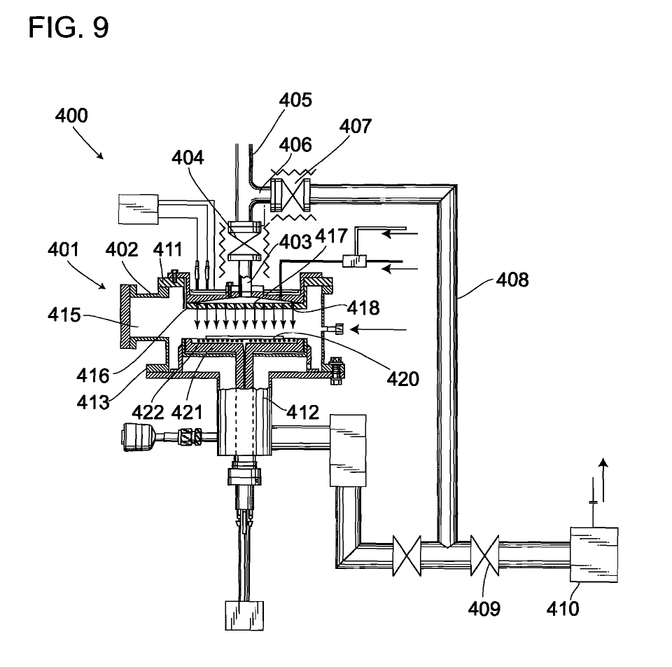

In FIG. 1 where the same portions as those described in FIG. 9 are denoted by the same reference numerals, reference numeral 1 shows a gas shower type heat CVD apparatus serving as a semiconductor production apparatus as a whole, constituted such that a series of ALD operations performed by intermittently supplying a raw material gas from a upper portion of the reaction chamber 402 can be performed.

The gas shower type heat CVD apparatus 1 for manufacturing semiconductors according to the present invention comprises a CVD section 2 and a vaporizer 3 for CVD mounted in this CVD section 2, such that a carrier gas is always able to be supplied from the vaporizer 3 for CVD to the reaction chamber 402 of the CVD section 2 at the time of the ALD operation.

The internal 415 of the reaction chamber 402 is kept at a predetermined temperature, using a heater (not shown) provided on the outside surface of the reaction-chamber body 413. Further, the reaction-chamber body 413 has a door part 4 at a predetermined location, so that the substrate 420 can be taken in and out from the internal 415 of the reaction chamber through this door part 4.

Further, an oxidization gas supply port 5 is provided in the reaction-chamber body 413 so that the oxidization gas (e.g., O₂) can be supplied through the oxidization gas supply port 5 to the internal 415 of the reaction chamber. A shower plate 416 is provided in the upper portion of the reaction chamber interior 415, while a heater 422 for the substrate stage is provided in the substrate stage 421 and in the inside of the substrate stage 421.

The shower plate 416 diffuses the raw material gas supplied to the interior space 417 through the gas ejecting hole 418 in a manner capable of spraying the raw material gas uniformly on the substrate 420 laid on the substrate stage 421. In the meantime, reference numeral 8 designates the vaporizer which, in the case that a water vapor H₂O is required as an oxidization gas, for example, can evaporate H₂O and supply the same into the interior space 417 of the shower plate 416, using oxidization gas O₂ as a carrier gas.

A shower plate heater 10 and a temperature sensor 11 are provided on the upper surface of the shower plate 416. Based on the temperature detected by the temperature sensor 11, heating control of the shower plate heater 10 is carried out through a control unit 12 so that the internal 415 of the reaction chamber and etc. can be heated to a predetermined temperature. In the meantime, a heater wiring 13 is connected to this shower plate heater 10.

The heater 422 for use with the substrate stage is constituted such that heating control thereof is carried out through the control unit 15, based on the temperature detected by the temperature sensor 14 so that the substrate stage 421 can be heated to a predetermined temperature. Incidentally, a heater wiring 16 is connected to this heater 422 for use with the substrate stage. A pressure gauge 412a for measuring the pressure in the interior 415 of the reaction chamber is provided in the reaction-chamber supporting part 412.

Moreover, the reaction-chamber supporting part 412 is communicated with the exhaust tube 17 extending to an exhaust vacuum pump 410, and a trap 18 is provided in the mid stream of this exhaust tube 17. Thus, the carrier gas and the raw material gas supplied to the internal 415 of the reaction chamber from the vaporizer 3 for CVD are allowed to pass through the exhaust tube 17 to be led to the trap 18, where specific toxic substances in the exhaust gas are removed, and then discharged from the vacuum pump 410 via the exhaust valve 409 and the like.

In addition to the foregoing structure, the reaction chamber 402 has the vaporizer 3 for CVD connected therewith at its gas introduction port 403 through the reaction-chamber side valve 404. It is to be noted herein that the gas shower type heat CVD apparatus 1 of the present invention does not perform the opening or closing operation of the reaction-chamber side valve 404 and the vent side valve 407 that has heretofore been performed in the conventional CVD apparatus 400 (FIG. 9) at the time of the ALD operation for forming a thin film of one atomic layer or one molecular layer one by one on the substrate 420, but allows the reaction-chamber side valve 404 to be always kept in an opened state, and the vent side valve 407 to be always kept in a closed state.

Thus, the carrier gas can always be supplied to the reaction chamber 402 from the vaporizer 3 for CVD at the time of the ALD operation. In addition, the carrier gas supplied to the reaction chamber 402 is always dischargeable from the exhaust vacuum pump 410 through the exhaust tube 17.

Moreover, the raw material gas obtained by evaporating only the material solution quantitated by the vaporizer 3 for CVD are capable of being supplied to the reaction chamber 402 at a predetermined moment.

Thus, inside the reaction chamber interior 415, a raw material gas is sprayed uniformly on the substrate 420, a and heated by a heating means such as a heater to thereby cause chemical reaction so that a thin film of one atomic-layer or one molecular layer of a desired film thickness can be formed on the substrate 420.

That is, in the gas shower type heat CVD apparatus 1, when the supply of the raw material gas obtained by evaporating only the material solution quantitated by the vaporizer 3 for CVD ceases, then only the carrier gas is supplied to the internal 415 of the reaction chamber again from the vaporizer 3 for CVD.

Thus, the thin film of one atomic layer or molecular layer of a desired thickness can be formed on the substrate 420 even though the reaction-chamber side valve 404 remains in an opened state, and the vent side valve 407 in a closed state.

Thus, the gas shower type heat CVD apparatus 1 is allowed to evaporate only the material solution of a predetermined quantity determined according to the film thickness of one atomic layer or one molecular layer formed on the substrate 420 as a thin-film formation subject, so that this raw material gas is intermittently supplied to the internal 415 of the reaction chamber.

Thus, it is possible to form a thin film of one atomic layer or one molecular layer of a desired film thickness can be formed sequentially on the substrate 420, without performing the opening or closing operation of the reaction-chamber side valve 404 and the vent side valve 407 each time.

### (1-2) The Detailed Structure of the Vaporizer for CVD

Next, the detailed structure of the vaporizer 3 for CVD is explained below. This vaporizer 3 for CVD comprises an evaporation mechanism 20 and a material-solution supply mechanism 21 provided in the evaporation mechanism 20. The evaporation mechanism 20 is connected with the gas introduction port 403 of the reaction chamber through the reaction-chamber side valve 404.

In this case, the vaporizer 3 for CVD is constituted so that the carrier gas may be always supplied to the reaction chamber 402 by the evaporation mechanism 20, while almost all the material solution of the predetermined quantity supplied from the material-solution supply mechanism 21 may be reliably evaporated by the evaporation mechanism 20.

### (1-2-1) The Structure of the Evaporation Mechanism

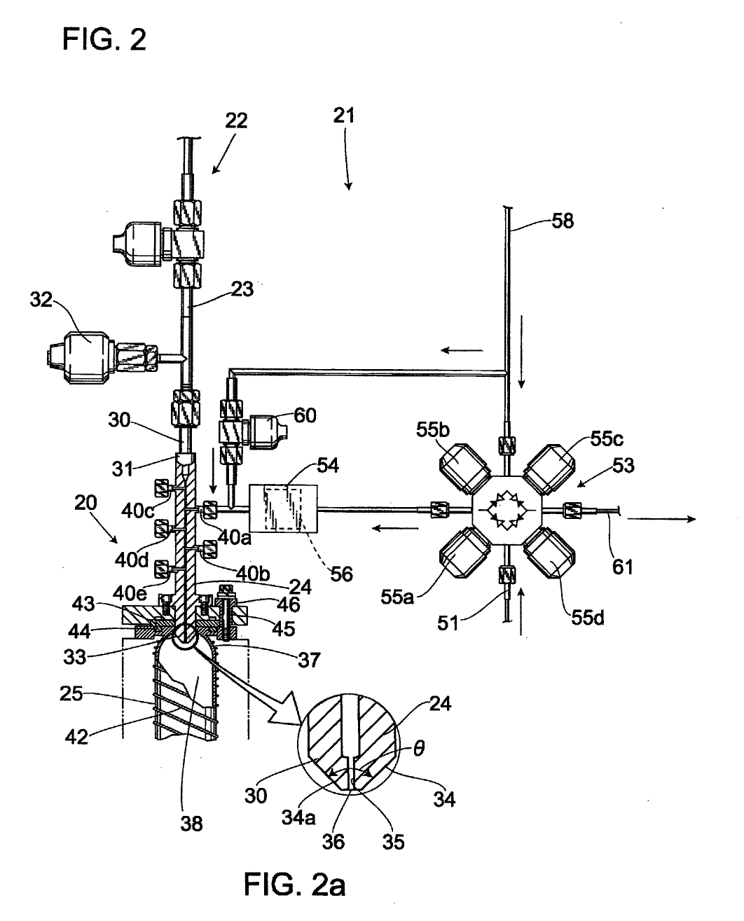

First, the evaporation mechanism 20 is explained hereinbelow. As shown in FIG. 2, in the evaporation mechanism 20, the carrier gas passage 22 for supplying various carrier gases, such as nitrogen or argon gas, to the internal 415 of the reaction chamber is constituted of a carrier gas tube 23, the orifice tube 24 and the evaporating section 25.

In a preferred form of the invention, the evaporation mechanism 20 is constituted such that a proximal end of the carrier gas tube 23 (namely, an inlet of the carrier gas passage 22) is connected with a supply mechanism (not shown) for supplying a carrier gas, while a distal end 30 of the carrier gas tube 23 is connected with a proximal end 31 of the orifice tube 24, so that a high-speed carrier gas can be supplied to the orifice tube 24 from the carrier gas tube 23.

Incidentally, between the proximal end of the carrier gas tube 23 and the supply mechanism are provided N₂ supplying valve and a mass flow controller (not shown). Moreover, a pressure transducer 32 is attached to the carrier gas tube 23.

In the meantime, the pressure transducer 32 is always monitoring the pressure of the carrier gas in the carrier gas tube 23 and its change, through the accurate measurement and record thereof. The pressure transducer 32 transmits to a control section (not shown) an output signal having a signal level according to the pressure level of the carrier gas.

Thus way, the pressure measurement result of the carrier gas is displayed on a display (not shown) based on the output signal in order for an operator to be able to monitor the same. The operator can monitor the clogging of the carrier gas passage 22 based on the measurement result of the pressure.

The carrier gas tube 23 is designed so that an internal diameter thereof is greater than an internal diameter of the orifice tube 24, thus enabling the flow velocity of the carrier gas supplied to the orifice tube 24 from the carrier gas tube 23 to be made even greater.

The orifice tube 24 is arranged vertically, including a convex portion 34 of a trapezoidal cone shape at a distal end 33, said convex portion 34 having an orifice 35 at an apex thereof. Thus, with the orifice tube 24 having the convex portion 34 provided at the distal end, a slope 34a is formed in a perimeter of an atomizing opening 36 at the tip end of the orifice 35, thus making it less likely for a residue to stay in the atomizing opening 36, enabling the inhibiting of clogging of the atomizing opening 36.

Incidentally, in the present embodiment, an apex angle, (theta) of the convex portion 34 may preferably be an acute angle ranging from 45 to 135 degrees, more preferably from 30 to 45 degrees, thus making it possible to prevent the atomizing opening 36 from being clogged with the material compounds deposited.

The orifice 35 of the atomizing opening 36 is designed so as to have an internal diameter smaller than that of the orifice tube 24 so that the flow velocity of the carrier gas supplied to the orifice 35 from the orifice pipe 24 may be even greater. The tip end of the orifice 35 is arranged here so that it may project in the interior space 38 of the evaporating section 25 due to the convex portion 34 of the orifice pipe 24 being inserted into the proximal end 37 of the evaporating section 25.

In addition to the foregoing structure, the orifice pipe 24 is in fluid communication with a plurality of connecting pipes 40a-40e (five, for example in this case) from the proximal end 31 to the convex portion 34. A hereinafter-described material-solution supply mechanism 21 is provided in each of these connecting pipes 40a-40e. Thus, the orifice pipe 24 is constituted so that the material solution of a predetermined quantity may be supplied from the material-solution supply mechanism 21 through the connecting pipes 40a-40e.

In that case, the orifice pipe 24 is constituted such that the carrier gas flowing at a high speed is sprayed against the material solution supplied, for example from the connecting pipe 40a so that the material solution is turned into the form of fine particles or mists to thereby be dispersed into the carrier gas, and then atomized into the evaporating section 25 through the orifice 35 at high speed (230 m/sec-350 m/sec).

In the case of the present embodiment, the orifice pipe 24 is designed to have an internal diameter of about, phi 1.0 mm, a vertically-extending longitudinal length of about 100 mm, and the internal diameter of the orifice 35 being set at about, phi 0.2-0.7 mm, so that the carrier gas can flow at a high speed thereinside.

The evaporating section 25 connected with the orifice pipe 24 is formed tubular and is arranged vertically like the orifice pipe 24. As shown in FIG. 2, the evaporating section 25 is formed so as to have an internal diameter notably greater than the internal diameter of the orifice pipe 24 so that the pressure in the evaporating section 25 may become smaller than the pressure in the orifice pipe 24.

Thus, such a great difference in pressure is provided between the orifice pipes 24 and the evaporating section 25, whereby the material solution and the carrier gas are allowed to blow off from the distal end 36 of the orifice pipe 24 at high speed (for example, 230 m/sec-350 m/sec) so that they may be expanded within the interior space 38.

In the present embodiment, the pressure in the evaporating section 25 is set at about 10 Torr, while the pressure in the orifice pipe 24 at about 500-1000 Torr, and thus a great difference in pressure is provided between the evaporating section 25 and the orifice pipe 24.

Incidentally, whilst the pressure of the carrier gas after a flow rate control fluctuates with a carrier gas flow rate, a solution flow rate and the size of the orifice 35, it is desirable that the size of the atomizing opening 36 is finally chosen to control the pressure of the carrier gas so as to set the same to 500-1000 Torr.

In addition, in the perimeter of the evaporating section 25, there is provided a heater 42 as a heating means between the proximal end 37 and the distal end 41 (namely, the outlet of the carrier gas passage 22), as shown in FIG. 1 so that the evaporating section 25 may be heated to about 270 degrees C. by this heater 42. In the present embodiment, the proximal end 37 of the evaporating section 25 is formed into a substantially hemisphere shape, and thus the proximal end 37 side can be heated evenly by the heater 42.

In this way, the evaporating sections 25 is constituted such that the material solution dispersed and turned into misty form by the high-speed carrier gas flow within the orifice pipe 24 may be instantly heated and momentarily evaporated by the heater 42. As that moment, it is desirable that a period from the time the material solution was mixed within the orifice pipe 24 until it is atomized into the evaporating section 25 be extremely short (preferably less than 0.1 to 0.002 second). Owing to such a high-speed carrier gas flow, the material solution is turned into fine particulars or misty form, immediately after being dispersed within the orifice pipe 24, and is evaporated within the evaporating section 25 instantaneously. Moreover, such a phenomenon that only a solvent evaporates is inhibited.

It is to be noted herein that by atomizing the material solution and the carrier gas into the evaporating section 25 at high speed, a mist size can be further miniaturized (a mist diameter being one micrometer or less), thus enabling an increase of an evaporation area as well as an increase of an evaporation rate. In the meantime, one-digit decrease of a mist size will result in one-digit increase of an evaporation area.

It is preferable to design the angle of the atomizing opening 36 and the size of the evaporating section 25 so that the mist ejected from the atomizing opening 36 may not collide with the inner wall of the evaporating section 25. It is because if the mist collides with the inner wall of the evaporating section 25, it will adhere to the wall surface, and thus the evaporation area will decrease extraordinarily and the evaporation rate will fall. Also, it is because the mist adhered to the wall of the adhered to the evaporating-section 25 wall for a long time is sometimes thermally decomposed and changes into a non-evaporable compound.

Moreover, the evaporating section 25 is decompressed thereinside, and thus sublimation temperature of the material compounds contained in each material solution can be lowered. As a result, the material solution can be evaporated easily with the heat from the heater 42.

Thus, the evaporating section 25 evaporates the material solution, supplies it as a raw material gas to the reaction chamber 402, where a thin film of one atomic layer or one molecular layer is formed in this reaction chamber 402 through CVD method.

In the meantime, the proximal end 37 of the evaporating section 25 has an adiabator 43 between the orifice pipes 24 and itself so that the heat from the evaporating section 25 may be less likely to be transmitted to the orifice pipe 24 with this adiabator 43. Incidentally the hermetic seal of the proximal end 37 of the evaporating section 25 is carried out by an O-ring 44. Moreover, another adiabator 46 is provided in a coupling member 45 which couples the orifice pipe 24 with the evaporating section 25.

It is desirable that the mist sprayed from the orifice 35 does not wet the inner wall of the evaporating section 25. This is because an evaporation area decreases extraordinarily if the inner wall is wet, as compared with just being misty. In other words, it is desirable to employ such a construction that the inner wall of the evaporating section 25 does not become tainted at all. Moreover, it is desirable to form the inner wall of the evaporating section 25 in mirror finish so that the dirt or taint on the inner wall of the evaporating section 25 can be evaluated easily.

According to the evaporation mechanism 20, the material solution is atomized instantaneously by a high-speed carrier gas flow so that it can be easily evaporated by the heat of the heater 42. As a result, even if the material solution is the one obtained by dissolving a hardly evaporable material compound in solvent, yet it is able to be evaporated in the evaporating section 25 easily.

For example, in the case that a SBT (tantalic acid strontium bismuth) film is formed on the substrate 420, it is possible to use Sr[Ta(OEt)5(OEtOMe)]2, Bi(OtAm)3 as material compounds, and it is preferable to use toluene as a solvent. Moreover, when forming a PZT (titanic acid lead zirconate) film on the substrate 420, it is possible to use as materials compounds Pb(DPM)2, Zr(DIBM)4, Ti(Oi-Pr)2(DPM)2 or Pb(METHD)2, Zr(MMP)4, and Ti(MMP)4, and it is preferable to use toluene as a solvent.

Moreover, according to the evaporation mechanism 20, the carrier gas pressurized in the carrier gas tube 23 so as to flow at a high speed is introduced into the orifice pipe 24 (for example, carrier gas being 500-1000 Torr, 200 ml/min-2 L/min), the temperature rise in the material solution can be inhibited in the orifice pipe 24.

According to the evaporation mechanism 20, therefore, evaporation of the solvent only in the material solution in the orifice pipe 24 can be inhibited, and thus it is possible to prevent the concentration of the material solution from becoming too high in the orifice pipe 24, thus enabling the inhibition of viscosity rise and the deposition of the material compound.

Furthermore, according to the evaporation mechanism 20, the material solution dispersed in the carrier gas can be evaporated by the evaporating section 25 instantaneously, and thus it is possible to prevent only the solvent in the material solution from being evaporated in the orifice 35 or in the vicinity thereof, and thus the clogging of the orifice 35 can be deterred. Thus way, continuous duty time of the vaporizer 3 for CVD can be lengthened.

### (1-2-2) Structure of the Material-Solution Supply Mechanism

Next, the material-solution supply mechanism 21 provided in the foregoing evaporation mechanism 20 is explained below. Although the material-solution supply mechanism 21 for determining the quantity of the material solution, is provided in each of the connecting pipes 40a-40e, the respective material-solution supply mechanisms 21 only differ in the kind of the material solution supplied to the orifice pipe 24, and all of them have the same structure. For the sake of simplicity, only the material-solution supply mechanism 21 provided in the connecting pipe 40a is explained hereinbelow.

The connecting pipes 40a-40e are arranged at the orifice pipe 24 so that the respective openings may not face each other, whereby, for example, the material solution supplied to the orifice pipe 24 from the opening of the connecting pipe 40a is reliably prevented from flowing into the openings of other connecting pipes 40b-40e.

In that case, as shown in FIG. 1, the material-solution supply mechanism 21 is constituted such that the material solution stored in a material solution storage tank 50 may be supplied to the orifice pipe 24 by allowing it pass through the predetermined material solution passage 51 via the liquid mass flow controller (LMFC) 52, a block valve 53, and the micro-metering pump 54 in sequence. This liquid mass flow controller 52 serves to control the flow rate of the material solution flowing through the material solution passage 51.

As shown in FIG. 2, the block valve 53 comprises first to fourth switching valves 55a-55d, controlled by a control section which is not shown herein.

In practice, when supplying a material solution to the orifice pipe 24, the block valve 53 is capable of supplying the material solution to the micro-metering pump 54 by switching only the first switching valve 55a into an opened state while the other switching valves 55b-55d into a closed state.

The micro-metering pump 54 is controlled by the control section together with the block valve 53 so that the material solution of predetermined quantity according to the film thickness of one atomic layer or one molecular layer formed on the substrate 420 can be stored in the storage section 56, and it is capable of determining quantity of the material solution supplied from the material solution tank 50.

Thus, the micro-metering pump 54 serving as a material solution discharging means is capable of storing the material solution supplied from the material solution tank 50 once in the storage section 56, according to the film thickness of one atomic layer or one molecular layer formed on the substrate 420 so that it may be set apart from the material solution supplied from the material solution tank 50.

The capacity of the storage section 56 is preset so that the material solution of a predetermined quantity most suitable for forming one atomic layer or one molecular layer may be stored therein, whereby the material solution of an optimal predetermined quantity for forming the film thickness of one atomic or molecular layer can be quantitated easily and reliably, by simply storing the material solution in the storage section 56.

Once the micro-metering pump 54 stores the material solution of such predetermined quantity in the storage section 56, then it will wait for a control signal from the control section. Then, if a predetermined control signal is received from the control section, the micro-metering pump 54 is then capable of supplying the material solution of the predetermined quantity stored in the storage section 56 to the orifice pipe 24 at a predetermined moment.

Accordingly, the orifice pipe is allowed to have such determined quantity of the material solution supplied to the carrier gas flowing at high speed, which in turn changes the material solution into the form of fine particles or mists, so as to be supplied to the evaporating section 25 with such misty material solution dispersed in the carrier gas.

In addition to the foregoing structure, the material-solution supply mechanism 21 is constituted, as shown in FIG. 1, such that when the material solution is not being supplied to the orifice pipe 24 from the micro-metering pump 54, the solvent stored in a solvent tank 57 may be supplied to the orifice pipe 24 by allowing it to pass through a predetermined solvent passage 58 via the liquid mass flow controller (LMFC) 59, the cut valve 60, and the connecting pipe 40a in sequence.

In that case, the control section switches the second switching valve 55b and the third switching valve 55c into a closed state, while the cut valve 60 into an opened state, whereby the connecting pipe 40a is opened so as to be able to supply the solvent to the orifice pipe 24. Thus, it is possible to prevent the connecting pipe 40a from being clogged with a solid matter by allowing the solvent only to flow into the orifice pipe 24 from the connecting pipe 40a.

On the other hand, the control section switches the second switching valve 55b and the cut valve 60 into a closed state, while the third switching valve 55c into an opened state, thereby allowing the solvent to flow into a vent tube 61 via the block valve 53 to be exhausted.

Furthermore, in the case that the control section switches the first switching valve 55a into a closed state so that the material solution is not being supplied to the micro-metering pump 54, the control section switches the third switching valve 55b and the cut valve into a closed state, while the second switching valve 55b into an opened state, whereby the solvent can be supplied to the orifice pipe 24 via the block valve 53, micro-metering pump 54 and the connecting pipe 40a in sequence. Thus, it is possible to prevent the micro-metering pump 54 from being clogged with a solid matter by allowing the solvent only to flow into the micro-metering pump 54.

In the meantime, the control section switches the first switching valve 55a, the second switching valve 55b and the third switching valve 55c into a closed state, while the fourth switching valve 55d into an opened state, thereby allowing the material solution to flow into a vent tube 61 via the block valve 53 to be exhausted.

### (1-3) Operation and Effect

According to the foregoing structure, the vaporizer 3 for CVD of the invention is provided with the micro-metering pump 54 in the material solution passage 51 between the material solution tank 50 and the orifice pipe 24, determining the quantity of the material solution supplied from the material solution tank 50, using the micro-metering pump 54 to thereby store the material solution in the storage section 56 as much as required for forming the film thickness of one atomic layer or one molecular layer.

Subsequently, in the vaporizer 3 for CVD, the material solution of the predetermined quantity quantitated by the micro-metering pump 54 is supplied to the carrier gas flow that is always flowing towards the reaction chamber 402 at high speed in the orifice pipe 24.

Thus, the material solution of the predetermined quantity is turned into the form of fine particles or mists and dispersed in the carrier gas, and then the dispersed material solution is evaporated in the evaporation section 25 as it is to thereby be supplied to the reaction chamber 402 as a raw material gas.

According to the gas shower type heat CVD apparatus 1 performing a CVD process in this way, it is possible to supply, as a raw material gas, only the material solution of the predetermined quantity determined by the micro-metering pump 54 to the reaction chamber 402, thereby spraying the thus obtained raw material gas uniformly on the substrate 420, which is then heated by the heater 422 or the like, to thereby cause a chemical reaction on the substrate 420.

In the gas shower type heat CVD apparatus 1, if the material solution of the predetermined quantity determined by the micro-metering pump 54 is all supplied to the evaporation mechanism 20, then the supply of a raw material gas to the internal 415 of the reaction chamber is allowed to stop. As a result, only the carrier gas is supplied to the reaction chamber 402 again. Consequently, according to the gas shower type heat CVD apparatus 1 of the invention, the thin film of one atomic-layer or one molecular layer of a desired film thickness can be formed on the substrate 420, without performing the opening or closing operation of the reaction-chamber side valve 404 and the vent side valve 407.

Moreover, according to the gas shower type heat CVD apparatus 1, when it finishes carrying out the deposition operation for forming the thin film of one atomic layer or one molecular layer, the material solution of the predetermined quantity determined by the micro-metering pump 54 is supplied again to the evaporation mechanism 20 after a predetermined time, so that another thin film of one atomic layer or one molecular layer of a desired film thickness is formed on the substrate 420.

Thus, according to the gas shower type heat CVD apparatus 1 of the invention, such a deposition operation that only the predetermined quantity of the material solution determined by the micro-metering pump 54 is supplied to the evaporation mechanism 20 is repeated multiple times so that a raw material gas is supplied to the reaction chamber 402 intermittently, thus enabling the deposition of a predetermined thickness one by one. Consequently, a high-density and high-quality thin film can be formed on the substrate 420 in this way.

Thus, the gas shower type heat CVD apparatus 1 of the invention does not need to perform any opening or closing operation of the reaction-chamber side valve 404 and the vent side valve 407 that have been performed in conventional CVD apparatus 400 (FIG. 9) at the time of the ALD that repeats deposition operation, but evaporates only the material solution of the predetermined quantity precisely determined by the micro-metering pump 54 in the evaporation mechanism 20, and supplies the same as a raw material gas to the reaction chamber 402, thereby enabling forming a film of a desirable film thickness made of one atomic layer or one molecular layer within the reaction chamber 402.

Accordingly, the gas shower type heat CVD apparatus 1 of the invention enables a thin film of a desired thickness made of one atomic layer or one molecular layer to be formed on the substrate 420 one by one, while avoiding a raw material gas being thrown away by the opening or closing operation of the reaction-chamber side valve 404 and the vent side valve 407.

Moreover, the gas shower type heat CVD apparatus 1 of the invention allows the reaction-chamber side valve 404 to be always in an opened state while allowing the vent side valve 407 to be always in a closed state at the time of ALD operation so that the carrier gas from the vaporizer 3 for CVD may always be supplied to the reaction chamber 402, whereby pressure change in the reaction chamber 402 does not occur and thus the deposition process condition inside the reaction chamber 402 can be kept uniformly.

Furthermore, the gas shower type heat CVD apparatus 1 eliminates the need for frequent repetitions of the opening or closing operation of the reaction-chamber side valve 404 and the vent side valve 407 at the time of ALD operation, and thus it is possible to extend the operating lives of these reaction-chambers side valve 404 and the vent side valve 407. As a result, frequency of maintenance can be diminished to thereby avoid operating rates' falls as compared with the conventional ones.

Also, according to the gas shower type heat CVD apparatus 1 of the invention, the storage section 56 of the micro-metering pump 54 is preset so that the material solution of the optimal predetermined quantity for forming the film thickness of one atomic layer or one molecular layer may be stored, and thus the material solution of the optimal predetermined quantity for forming the film thickness of an one atomic layer or one molecular layer can be supplied to the evaporation mechanism 20 easily and reliably by simply storing the material solution in the storage section 56.

Moreover, the evaporation mechanism 20 used in the vaporizer 3 for CVD allows the material solution to be turned into the form of fine particles or mists within the orifice pipe 24 so as to be dispersed in the carrier gas in order for all the material solutions to be easily evaporated with heat, while controlling the temperature rise of the material solution in the orifice pipe 24, preventing the deposition of the material compounds, whereby all the material solution of the predetermined quantity precisely determined by the micro-metering pump can be evaporated precisely, so that an accurately constant quantity of raw material gases can always be supplied to the reaction chamber 402 in this way.

According to the above structure, the carrier gas continues to be supplied to the reaction chamber 402 at the time of ALD operation, while the material solution of predetermined quantity according to the film thickness of one atomic or molecular layer quantitated by the micro-metering pump 54 is intermittently supplied to the evaporation mechanism 20, and the raw material gas composed of the material solution of the predetermined quantity thus obtained is supplied to the reaction chamber 402 together with the carrier gas.

Accordingly, the gas shower type heat CVD apparatus 1 of the invention enables a thin film of a desired thickness made of one atomic layer or one molecular layer to be formed on the substrate 420 one by one, while avoiding a raw material gas being thrown away by the opening or closing operation of the reaction-chamber side valve 404 and the vent side valve 407. Thus way, the efficiency in the use of a raw material gas can be improved remarkably, according to the quantity of the raw material gas that is not thrown away in the process of forming a thin film of one atomic or molecular layer one by one.

Moreover, the gas shower type heat CVD apparatus 1 of the invention allows the reaction-chamber side valve 404 to be always in an opened state at the time of ALD operation so that the carrier gas from the vaporizer 3 for CVD may always be supplied to the reaction chamber 402, so that pressure change in the reaction chamber 402 does not occur and thus the deposition process condition inside the reaction chamber 402 can be kept uniform, thus enabling the film having a film thickness of one atomic or molecular layer according to the supplied raw material gas to be uniformly formed on the substrate 420.

Furthermore, the gas shower type heat CVD apparatus 1 eliminates the need for frequent repetitions of the opening or closing operation of the reaction-chamber side valve 404 and the vent side valve 407 at the time of ALD operation, and thus it is possible to extend the operating lives of these reaction-chamber side valve 404 and the vent side valve 407. As a result, frequency of maintenance can be diminished to thereby improve productivity.

### (2) Second Embodiment

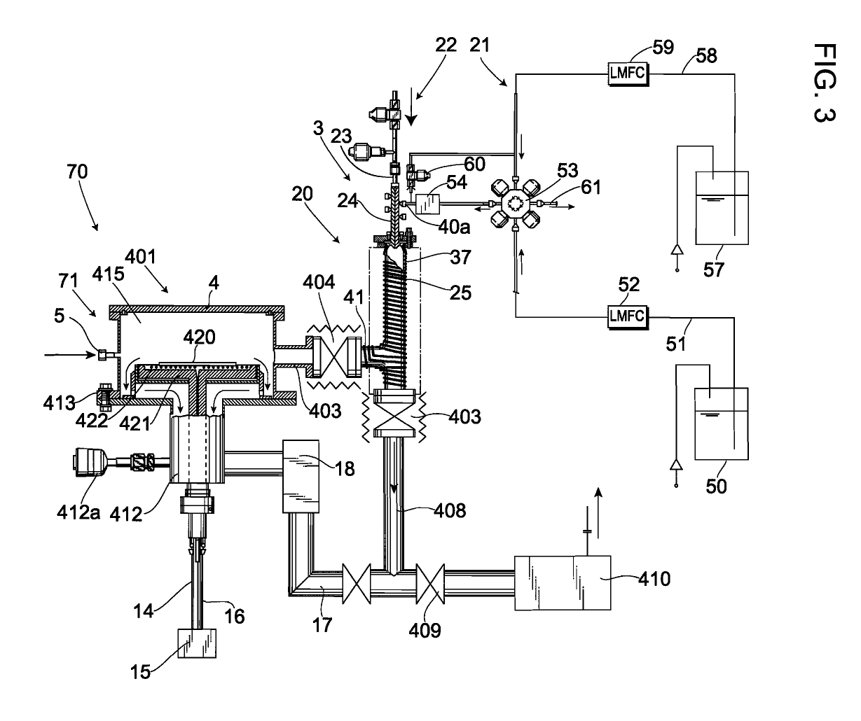

In FIG. 3 where the same portions as those illustrated in FIG. 1 are designated by the same reference numerals, numeral 70 shows a heat CVD apparatus as a semiconductor production apparatus, which has the same structure as the foregoing first embodiment, except that it is constituted so as to be able to perform a series of ALD operations accompanied with the intermittent supply of the raw material gas from the side of the reaction chamber 71. Since the heat CVD apparatus 70 performing such a CVD process is also equipped with the vaporizer 3 for CVD, the same effect as mentioned above can be obtained.

### (3) Third Embodiment

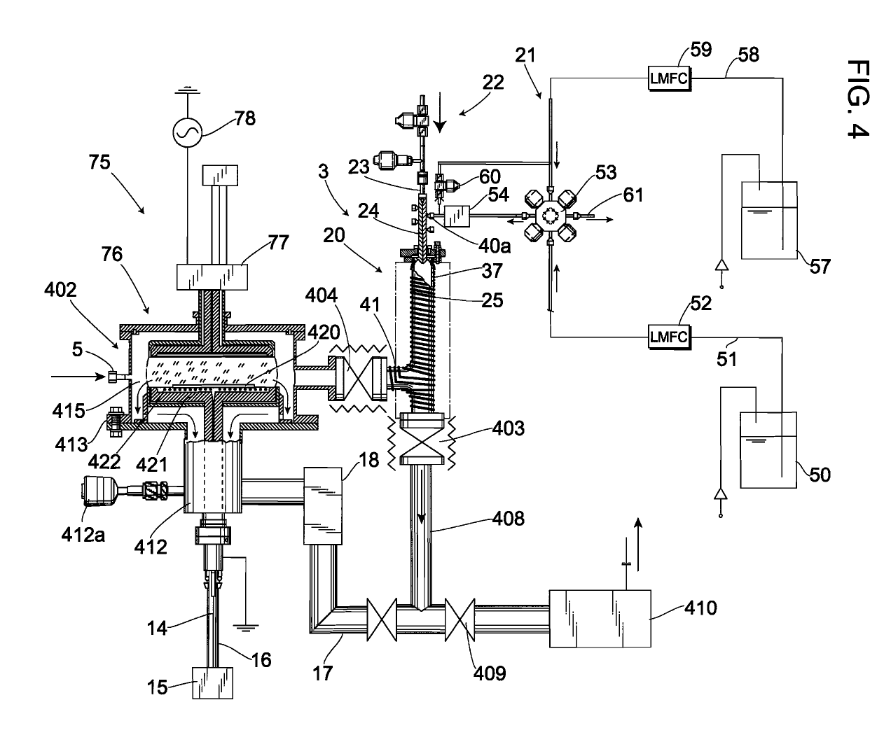

In FIG. 4 where the same portions as those illustrated in FIG. 1 are designated by the same reference numerals, numeral 75 shows a plasma-CVD apparatus as a semiconductor production apparatus, which differs from the foregoing first embodiment in the structure of the CVD section 76.

In the present embodiment, an RF (Radio Frequency) plasma generator electrode 77 is provided in the reaction chamber 402, so that plasma can be generated within the reaction chamber 402 by the RF plasma generator electrode 77. In the meantime, numeral 79 denotes a noise cutoff filter.

In that case, an RF power supply 78 is arranged above the reaction chamber 402, and the RF power supply 78 is equipped with the plasma generator electrode 77. Thus, the plasma-CVD apparatus 75 allows plasma to be generated in the reaction chamber to cause a chemical reaction on the substrate 420 so that the thin film of one atomic layer or one molecular layer of a desired film thickness. Since the plasma CVD apparatus 75 performing such a CVD process is also equipped with the vaporizer 3 for CVD, the same effect as the foregoing first embodiment can be obtained.

### (4) Fourth Embodiment

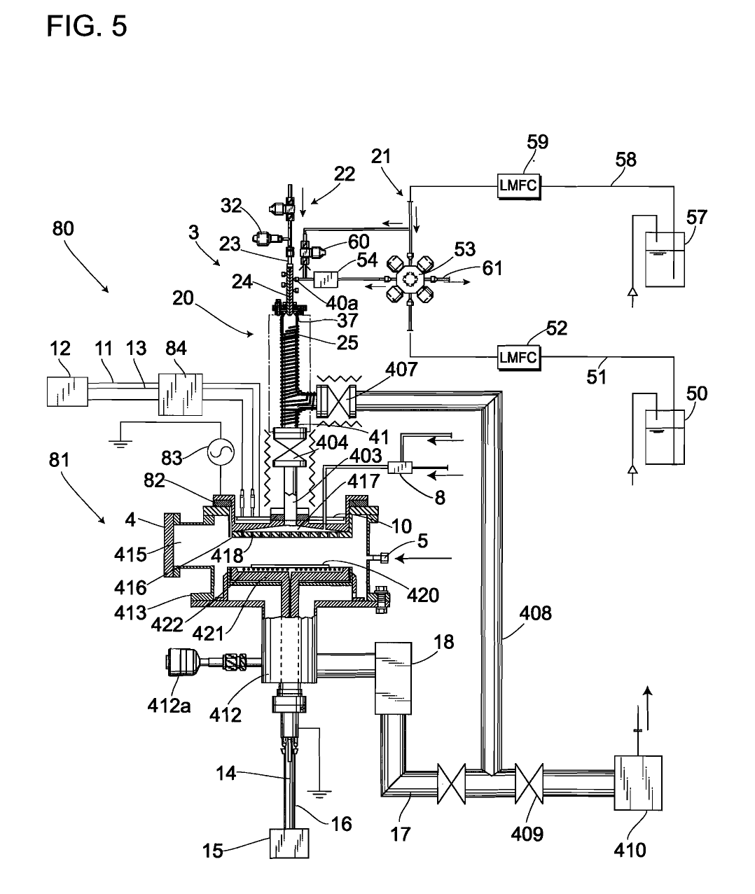

In FIG. 5 where the same portions as those illustrated in FIG. 1 are designated by the same reference numerals, numeral 80 shows a shower type plasma-CVD apparatus as a semiconductor production apparatus, which differs from the first embodiment in the structure of the CVD section 81, comprising a plasma system and a shower plate 416.

In the present embodiment, the CVD section 81 is formed with an RF (Radio Frequency) power supply 83 via an insulating material 82 above the shower plate 416, and the shower plate heater 10 is provided thereabove. In addition, numeral 84 denotes a noise cutoff filter for preventing RF voltage from entering into the control unit 12. Since the shower type plasma-CVD apparatus 80 performing such a CVD process is also equipped with the vaporizer 3 for CVD, the same effect as the foregoing first embodiment can be obtained.

### (5) Fifth Embodiment

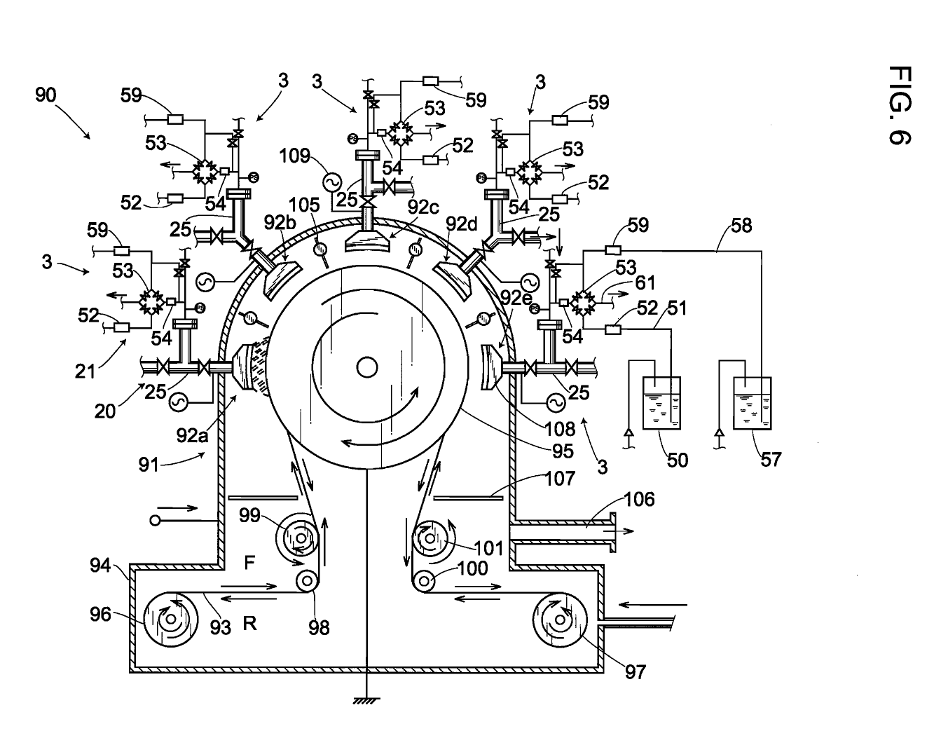

In FIG. 6, numeral 90 shows a roller type plasma-CVD apparatus as a semiconductor production apparatus, comprising two or more vaporizers 3 for CVD in a roller type CVD section 91.

In the roller type plasma-CVD 90, a plurality of plasma generators 92a-92e are provided in the roller type CVD section 91, in which a tape 93 for forming a film thereon is allowed to travel in a forward direction F, or otherwise, in a reverse direction R, whereby a thin film is formed in each of the plasma generators 92a-92e so that multi-layered films made from different materials can be formed.

In practice, according to this roller type plasma-CVD apparatus 90, the vaporizer 3 for CVD of the present invention is provided in each of the plasma generators 92a-92e, and thus the same effect as the foregoing first embodiment can be obtained.

Incidentally, in this roller type plasma-CVD apparatus 90, a first rolling-up roller 96 and a second rolling-up roller 97 are arranged on both sides of the deposition roller 95 in the reaction chamber 94. Moreover, a first feed roller 98 and a first tension control roller 99 are arranged at one side of the deposition roller 95, while a second feed roller 100 and a second tension control roller 101 are arranged at the other side of the deposition roller 95. In the meantime, the diameter of the deposition roller 95 is as large as 1,000-20,000 mm, and a width thereof is 2 m, for example.

Accordingly, in the roller type plasma-CVD apparatus 90, a traveling path for the tape 93 to travel thereon is provided from the first wind-up roller 96 through the first feed roller 98, the first tension control roller 99, the deposition roller 95, the second tension control roller 101, the second feed roller 100 up to the second wind-up roller 97, whereby the tape 93 for forming a film thereon can travel along the traveling path in the direction from the first rolling-up roller 96 to the second rolling-up roller 97 (forward direction F), as well as in the direction from the second rolling-up roller 97 to the first rolling-up roller 96 (reverse direction R).

In that case, the plasma generators 92a-92e are each provided in response to respective areas on the deposition roller 95, so that the vaporizer 3 for CVD is allowed to act upon respective portions of the tape 93 located on the areas to thereby form a thin film. Moreover, each of the plasma generators 92a-92e and the vaporizer 3 for CVD are controlled to be able to set various CVD and/or film conditions individually, enabling any of them to perform or stop deposition process individually.

In the meantime, a partition plate 105 is arranged between the adjacent ones of the plasma generators 92a-92e, in order to prevent an interference of a raw material gas. Incidentally, numeral 106 designates an exhaust tube, 107 an anti-adhesive plate, 108 a gas shower electrode and 109 an RF power supply, respectively. In the present embodiment, the deposition roller 95 is grounded, and the gas shower electrode 108 is connected to the terminal of the RF power supply 109, and thus the electric potential of the plasma generators 92a-92e is higher.

According to the roller type plasma-CVD apparatus 90 which performs such a CVD deposition process, the tape 93 for forming a film thereon is allowed to travel in the forward direction F or in the reverse direction R, which is repeated alternately so that a multilayer film of 50 layers-1000 layers, for example, can be formed in a comparatively efficient manner.

### (6) Sixth Embodiment

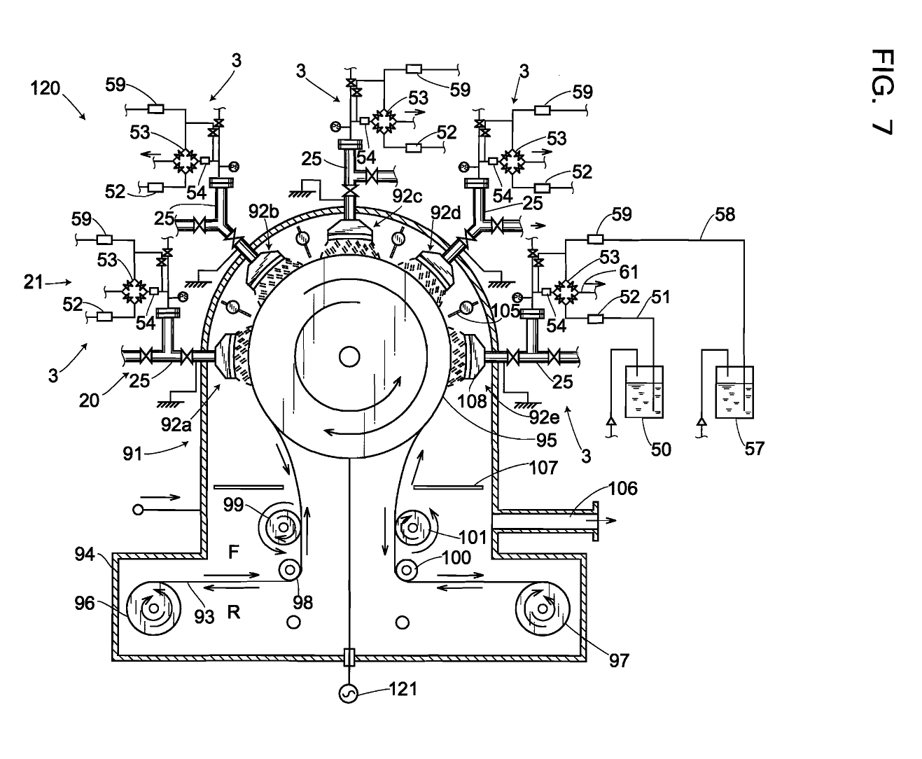

In FIG. 7 where the same portions as those illustrated in FIG. 6 are designated by the same reference numerals, numeral 120 shows a roller type plasma-CVD apparatus as a semiconductor production apparatus, which differs from the foregoing fifth embodiment in that the electric potential of the deposition roller 95 is higher. Namely, the roller type plasma-CVD apparatus 120 differs in that one terminal of one RF power supply 121 is connected to the deposition roller 95, while the gas shower electrode 108 of each of the plasma generators 92a-92e is grounded. Since such roller type plasma-CVD apparatus 120 also comprises the vaporizer 3 for CVD of the present invention, the same effect as the first embodiment can be obtained.

### (7) Seventh Embodiment

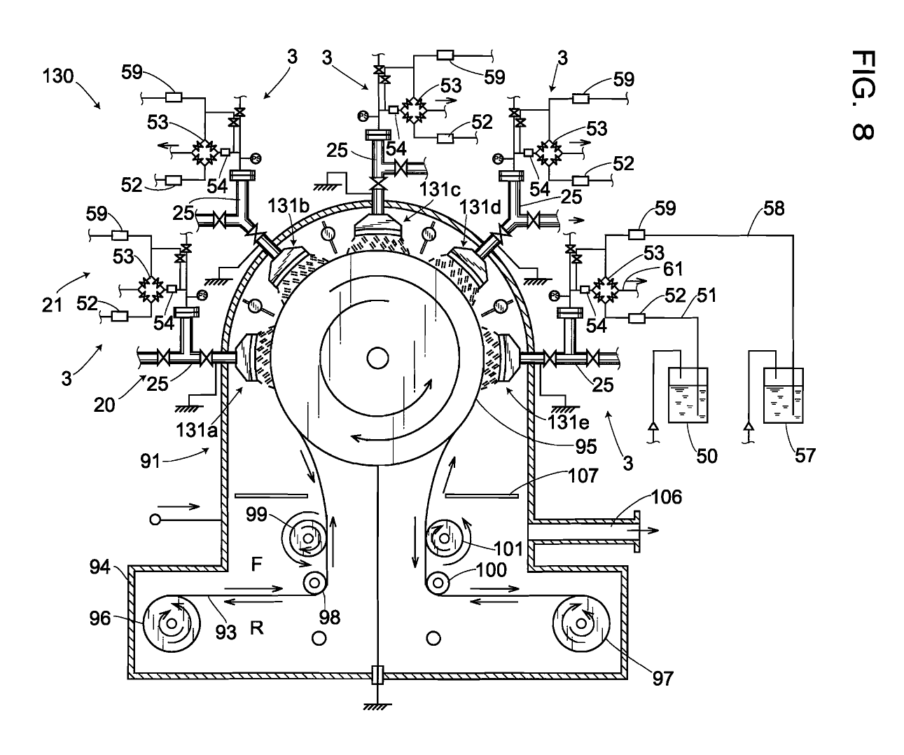

In FIG. 8 where the same portions as those illustrated in FIG. 6 are designated by the same reference numerals, numeral 130 shows a roller type heat CVD apparatus as a semiconductor production apparatus. The roller type heat CVD apparatus 130 differs from the foregoing fifth embodiment in that it is not provided with a plasma generator and no voltage is applied between the shower plate sections 131a-131e and the deposition roller 95. This roller type heat CVD apparatus 130 is constituted so that the tape 93 for forming a film thereon can be heated mainly by the deposition roller 95.

Since such roller type heat-CVD apparatus 130 also comprises the vaporizer 3 for CVD of the present invention provided in each of the shower plate sections 131a-131e, the same effect as the first embodiment can be obtained.

### (8) Other Embodiments

In the meantime, the present invention is not limited to the foregoing embodiments, and various modifications are possible. Although only one kind of the material solution is supplied to the evaporation mechanism 20 from the micro-metering pump 54 provided in the connecting pipe 40a in the foregoing embodiments, the present invention should not be limited thereto, but the material solutions of different kinds from each micro-metering pump 54 provided in the connecting pipes 40a-40e may be supplied to the evaporation mechanism 20 either at the same time or sequentially at intervals.

Moreover, although the foregoing embodiments employ the evaporation mechanism 20 constituted so that a material solution is atomized and changed into misty form instantaneously by the high-speed carrier gas flow so that it may be easily evaporated with the heat of the heater 42, the present invention should not be limited thereto, but an ordinary evaporation mechanism usually used for CVD may be employed.

In the case that such ordinary evaporation mechanism is employed, the evaporation section may not be provided in the vicinity of the gas introduction port 403 (FIG. 1) of the reaction chamber 402, but in the connecting pipes 40a-40e formed in a bifurcation of the conventional gas supply passage 405 as shown in FIG. 9 so that the raw material gas obtained in the evaporation section may be supplied to the gas supply passage 405 (FIG. 9) through the connecting pipes 40a-40e.

In other words, the object of the invention is achieved if the evaporation section is provided in a predetermined location between the outlet of the carrier gas passage 22 and the micro-metering pumps 54 so that when supplying a material solution to the evaporation section from the material solution tank 50, the material solution of predetermined quantity according to the film thickness of one atomic or molecular layer determined by the micro-metering pump 54 may be supplied to the evaporation mechanism 20, and only the raw material gas composed of the resultant material solution of the predetermined quantity may be supplied to the reaction chamber 402.

Furthermore, although the material solution determined by the micro-metering pump 54 is intermittently supplied to the evaporation mechanism 20 at regular intervals in the foregoing embodiments, the present invention should not be limited thereto, but the material solution determined by the micro-metering pump 54 may be intermittently supplied to the evaporation mechanism 20 at irregular intervals. In that case, the supply of the material solution may be performed plural times by the micro-metering pump 54, where necessary.

Still further, in the foregoing embodiments is proposed the use of an apparatus for CVD process, such as the heat CVD apparatus 70, the plasma-CVD apparatus 75, the shower type plasma-CVD apparatus 80, the roller type plasma-CVD apparatus 90, the roller type plasma-CVD apparatus 120, the roller type heat CVD-apparatus 130, etc. but the present invention should not be limited thereto but may be applicable to other various semiconductor production apparatus that perform various other processes such as an etching apparatus for performing etching process in the reaction chamber, a sputtering apparatus which performs a sputtering process in the reaction chamber, or an ashing process that perform ashing process in the reaction chamber, etc. Since the vaporizer of the present invention can be provided in the reaction chamber in these cases as well, the same effect as the above-mentioned embodiments can be obtained.

Furthermore, although in the foregoing embodiments is proposed the use of the deposition method performed in the deposition apparatus, as a semiconductor manufacturing method, the invention should not be limited thereto, but may be applied to other semiconductor manufacturing methods such as etching method.

Furthermore, although in the foregoing embodiments is proposed the use of the metering pump 54 to determine the material solution according to the quantity of one atomic or molecular layer, but the present invention should not be limited thereto. For example, the metering pump 54 may determine other various specific quantities such as the quantity according to a film thickness of 500 nm or less, In that case, it is possible to supply the material solution to the evaporation section 25 by the quantity according to a film thickness of 500 nm or less.

Moreover, although in the foregoing embodiments is proposed the use of the micro-metering pump 54 with a predetermined storage capacity of the material solution, the present invention should not be limited thereto. For example, a micro-metering pump whose storage capacity is variable depending on cases may be used.

Furthermore, although in the foregoing embodiments is proposed the use of the micro-metering pumps 54 as a material-solution discharge means, the present invention should not be limited thereto. As long as it is possible to determine a preset quantity of the material solution so as to be able to supply the same to the evaporation mechanism 20, other various material-solution discharge means may be used.

Furthermore, although in the foregoing embodiments is proposed the use of the solid material compound dissolved in solvent as the material solution, the present invention should not be limited thereto. For example, liquid material compound itself may be used as the material solution

1. A vaporizer for supplying a raw material gas to a reaction chamber, said material gas being obtained by evaporating a material solution, comprising:
a carrier gas passage for allowing the carrier gas to flow from an inlet toward an outlet;
a material solution passage to which said material solution is supplied;
a connecting pipe for communicating said carrier gas passage with said material solution passage;
a material solution discharging device determining quantity of said material solution supplied to said material passage to discharge the same to said connecting pipe;
an evaporating section provided between the outlet of said carrier gas passage and said material solution discharging device, said evaporating section evaporating a predetermined quantity of said material solution discharged from said material solution discharging device.

2. The vaporizer according to claim 1, wherein said material solution discharging device discharges said material solution intermittently to said connecting pipe.

3. The vaporizer according to claim 1, further comprising a solvent passage for supplying a purge solvent to said carrier gas passage.

4. The vaporizer according to claim 1, wherein said carrier gas passage comprises:
a carrier gas tube to which said carrier gas is supplied;
an orifice pipe having said carrier gas supplied from said carrier gas tube, said orifice pipe turning said material solution into the form of fine particles or mists to be supplied to said evaporating section with said material solution being dispersed into the carrier gas, and
wherein said evaporating section comprises a heating means for heating and evaporating said material solution dispersed in said carrier gas.

5. The vaporizer according to claim 1, wherein said material solution discharging device comprises a micro-metering pump.

6. The vaporizer according to claim 1, wherein said material solution discharging device determines quantity of said material solution supplied to said material solution passage so that the determined quantity thereof corresponds to that required for a film thickness of 500 nm or less to be formed on a substrate.

7. The vaporizer according to claim 6, wherein said determined quantity of the material solution corresponds to that required for forming one atomic layer or one molecular layer formed on said substrate.

8. The vaporizer according to claim 7, wherein said material solution discharging device comprises a storage section for storing a specific quantity of said material solution, corresponding to that required for forming one atomic layer or one molecular layer.

9. The vaporizer according to claim 8, wherein said material solution discharging device stores said specific quantity of the material solution supplied from a material solution tank in said storage section beforehand so that it may be discharged to said evaporating section at a predetermined moment.

10. A semiconductor production apparatus including a reaction chamber for placing a substrate thereon and a vaporizer for supplying a raw material gas to the reaction chamber, said material gas being obtained by evaporating a material solution,
wherein said vaporizer comprises:
a carrier gas passage for allowing the carrier gas to flow from an inlet toward an outlet;
a material solution passage to which said material solution is supplied;
a connecting pipe for communicating said carrier gas passage with said material solution passage;
a material solution discharging device determining quantity of said material solution supplied to said material passage to discharge the same to said connecting pipe;
an evaporating section provided between the outlet of said carrier gas passage and said material solution discharging device, said evaporating section evaporating a predetermined quantity of said material solution discharged from said material solution discharging device.

11. The semiconductor production apparatus according to claim 10, wherein said material solution discharging device discharges said material solution intermittently to said connecting pipe.

12. The semiconductor production apparatus according to claim 10, further comprising a solvent passage for supplying a purge solvent to said carrier gas passage.

13. The semiconductor production apparatus according to claim 10,
wherein said carrier gas passage comprises:
a carrier gas tube to which said carrier gas is supplied;
an orifice pipe having said carrier gas supplied from said carrier gas tube, said orifice pipe turning said material solution into the form of fine particles or mists to be supplied to said evaporating section with said material solution being dispersed into the carrier gas, and
wherein said evaporating section comprises a heater heating and evaporating said material solution dispersed in said carrier gas.

14. The semiconductor production apparatus according to claim 10, wherein said material solution discharging device comprises a micro-metering pump.

15. The semiconductor production apparatus according to claim 10, wherein said material solution discharging device determines quantity of said material solution supplied to said material solution passage so that the determined quantity thereof corresponds to that required for a film thickness of 500 nm or less to be formed on a substrate.

16. The semiconductor production apparatus according to claim 15, wherein said determined quantity of the material solution corresponds to that required for forming one atomic layer or one molecular layer formed on said substrate.

17. The semiconductor production apparatus according to claims 16, wherein said material solution discharging device comprises a storage section for storing a specific quantity of said material solution, corresponding to that required for forming one atomic layer or one molecular layer.

18. The semiconductor production apparatus according to claim 17, wherein said material solution discharging device stores said specific quantity of the material solution supplied from a material solution tank in said storage section beforehand so that it may be discharged to said evaporating section at a predetermined moment.

19. A process of producing a semiconductor in which a raw material gas obtained by evaporating a material solution is supplied into a reaction chamber where a substrate is surface treated, said method comprising:
a carrier gas supply step for supplying the carrier gas to said reaction chamber by allowing the carrier gas to flow from an inlet toward an outlet of a carrier gas passage;
a material-solution supply step for supplying said material solution to said material solution passage;
a quantitating step for determining quantity of said material solution supplied to said material solution passage;
a material solution discharging step for discharging a predetermined quantity of said material solution quantitated in the quantitating step to said connecting pipe communicating said carrier gas passage with said material solution passage; and
an evaporating step for evaporating said predetermined quantity of said material solution discharged in said material solution discharging step, using an evaporating section provided between the outlet of said carrier gas passage and a means for discharging said material solution.

20. The process of producing a semiconductor according to claim 19, wherein said material solution is discharged intermittently to said connecting pipe in said material solution discharging step.

21. The process of producing a semiconductor according to claim 19, comprising a purge solvent supply step for supplying a purge solvent to said evaporating section from said carrier gas passage through said connecting pipe, instead of said material solution discharging step and said evaporating step.

22. The process of producing a semiconductor according to claim 19, wherein said carrier gas supply step includes a sub-step for supplying said carrier gas to said orifice pipe from said carrier gas tube; and after the sub-step, said material solution is discharged to said orifice pipe in said material solution discharging step, so that said material solution turned into the form of fine particles or mists in said orifice pipe to be supplied to said evaporating section with said material solution being dispersed into the carrier gas, and then said material solution dispersed in said carrier gas through said evaporating step is heated by a heater provided in said evaporating section.

23. The process of producing a semiconductor according to claim 19, wherein quantity of said material solution is determined by a micro-metering pump in said quantitating step.

24. The process of producing a semiconductor according to claim 19, wherein in said quantitating step, quantity of said material solution supplied to said material solution passage is determined, corresponding to that required for forming a film of 500 nm or less thickness on said substrate.

25. The process of producing a semiconductor according to claim 24, wherein the quantity required for forming a film of 500 nm or less thickness corresponds to that required for forming one atomic layer or one molecular layer formed on said substrate.

26. The process of producing a semiconductor according to claim 25, wherein in said quantitating step, a specific quantity of said material solution is stored in a storage section, corresponding to that required for forming one atomic layer or one molecular layer.

27. The process of producing a semiconductor according to claim 26, wherein in said quantitating step, a specific quantity of the material solution supplied from a material solution tank is stored in said storage section beforehand, corresponding to that required for forming one atomic layer or one molecular layer so that it may be discharged to said evaporating section at a predetermined moment.
